(19) United States
(12) Patent Application Publication
(10) Pub. No.: US 2025/0267942 A1
(43) Pub. Date: Aug. 21, 2025

(54) DISPLAY SUBSTRATE AND METHOD FOR MANUFACTURING THE SAME

(71) Applicants: Nanjing BOE Display Technology CO.,LTD., Nanjing,Jiangsu (CN); BOE Technology Group Co., Ltd., Beijing (CN)

(72) Inventors: Youwei ZHANG, Beijing (CN); Yanlong LI, Beijing (CN)

(21) Appl. No.: 18/701,218

(22) PCT Filed: Mar. 31, 2023
(86) PCT No.: PCT/CN2023/085487

§ 371 Date: Apr. 13, 2024

(51) Int. Cl. H10D 86/40; H10D 86/01; H10D 86/60

(52) U.S. Cl. CPC H10D 86/471; H10D 86/0221; H10D 86/0231; H10D 86/443; H10D 86/60

(57) ABSTRACT

A display substrate and a method for manufacturing the same. The display substrate includes a base substrate, a buffer layer, and pixel units; the pixel units constitute multiple first pixel unit groups in a second direction, and multiple second pixel unit groups in a first direction; each first pixel unit group includes multiple pixel units in the first direction, each second pixel unit group includes multiple pixel units in the second direction; each pixel unit includes at least one thin film transistor; a gate electrode of each thin film transistor is farther away from the base substrate than an active layer thereof, an orthographic projection of the active layer on the base substrate covers of the gate electrode on the base substrate; the gate electrodes of the thin film transistors of adjacent pixel units in each first pixel unit group are electrically connected through a bridge structure.

### TECHNICAL FIELD

The present disclosure relates to the field of display technology, and particularly relates to a display substrate and a method for manufacturing the same.

### BACKGROUND

A Thin Film Transistor (TFT), serving as a switching control element or an integrated element of a peripheral driver circuit, is a core device in the display technology. Common structures of thin film transistors include a bottom gate type structure and a top gate type structure.

### SUMMARY

The present disclosure is directed to solve at least one of the problems in the related art, and provides a display substrate and a method for manufacturing the same.

In a first aspect, a technical solution adopted to solve the technical problem of the present disclosure is a display substrate, including a base substrate, a buffer layer arranged on the base substrate, and a plurality of pixel units arranged on a side, away from the base substrate, of the buffer layer; where the plurality of pixel units constitute a plurality of first pixel unit groups arranged side by side in a second direction, and a plurality of second pixel unit groups arranged side by side in a first direction; each of the first pixel unit groups includes a plurality of the pixel units arranged side by side in the first direction, and each of the second pixel unit groups includes a plurality of the pixel units arranged side by side in the second direction; each pixel unit includes at least one thin film transistor which is correspondingly arranged; where
a gate electrode of each thin film transistor is farther away from the base substrate than an active layer of the thin film transistor, and an orthographic projection of the active layer of the thin film transistor on the base substrate covers an orthographic projection of the gate electrode of the thin film transistor on the base substrate; and
the gate electrodes of the thin film transistors of adjacent pixel units in each first pixel unit group are electrically connected through a bridge structure.

In some implementations, the gate electrode includes a body structure and a first extension structure and a second extension structure connected to two ends of the body structure, respectively; and an included angle between an extending direction in which the body structure extends and the first direction is a first included angle ranging from 30° to 85°.

In some implementations, the gate electrode includes a body structure and a first extension structure and a second extension structure connected to two ends of the body structure, respectively; the first extension structure and the second extension structure are opposite in direction, and an included angle between an extending direction in which each of the first extension structure and the second extension structure extends and the first direction is a second included angle ranging from 0° to 10°

In some implementations, an included angle between an extending direction in which the active layer extends and the first direction is a third included angle ranging from 35° to 60°.

In some implementations, the bridge structure is located between two adjacent pixel units along the second direction.

In some implementations, the display substrate further includes a light shielding layer located on a side of the buffer layer close to the base substrate, where an orthographic projection of the light shielding layer on the base substrate at least covers an orthographic projection of a channel region of the active layer on the base substrate.

In some implementations, a ratio of a first width of the channel region in an extending direction in which the active layer extends to a first width of the light shielding layer in the extending direction in which the active layer extends ranges from 1:7 to 1:4.

In some implementations, a ratio of a second width of the channel region in in a direction perpendicular to an extending direction in which the active layer extends to a second width of the light shielding layer in the direction perpendicular to the extending direction in which the active layer extends ranges from 1:7 to 1:4.

In some implementations, the active layer at least includes a source contact region, a drain contact region, and a channel region sandwiched between the source contact region and the drain contact region;
the display substrate further includes a second insulating structure, a third insulating structure, a common electrode, a fourth insulating structure and a pixel electrode which are sequentially arranged on a side of the thin film transistors away from the base substrate, the pixel electrode being electrically connected with the drain contact region through a connection via hole sequentially penetrating through the fourth insulating structure, the third insulating structure and the second insulating structure; and
the connection via hole includes a first connection via hole penetrating through the second insulating structure, a second connection via hole penetrating through the third insulating structure and a third connection via hole penetrating through the fourth insulating structure, and outlines of orthographic projections of the first connection via hole, the second connection via hole and the third connection via hole on the base substrate are sequentially nested.

In some implementations, a ratio of an area of an orthographic projection of the first connection via hole on the active layer to an area of the drain contact region ranges from 1:9 and 1:4.

In some implementations, the second insulating structure is provided with first via holes, and the bridge structure is electrically connected to the gate electrodes of two adjacent thin film transistors in the same first pixel group through two first via holes respectively; and
an orthographic projection of each of the first via holes on the base substrate falls within the orthographic projection of the gate electrode on the base substrate.

In some implementations, the display substrate further includes a data line located on a side of the gate electrode away from the base substrate, where the data line is configured to provide a data voltage to the thin film transistor, and the bridge structure is disposed in a same layer as the data line.

In a second aspect, an embodiment of the present disclosure further provides a method for manufacturing a display substrate, including: providing a base substrate, forming a buffer layer on the base substrate, and forming a plurality of pixel units on a side of the buffer layer away from the base substrate; where the plurality of pixel units constitute a plurality of first pixel unit groups arranged side by side in a second direction, and a plurality of second pixel unit groups arranged side by side in a first direction; each of the first pixel unit groups includes a plurality of the pixel units arranged side by side in the first direction, and each of the second pixel unit groups includes a plurality of the pixel units arranged side by side in the second direction; the step of forming the pixel units at least includes: forming thin film transistors on a side of the buffer layer away from the base substrate; where
the step of forming the thin film transistors in the pixel units includes:
   sequentially forming a semiconductor layer, a first insulating layer and a first conductive layer on a side of the buffer layer away from the base substrate;
   patterning the first conductive layer to form a pattern including gate electrodes of the thin film transistors;
   patterning, after forming the gate electrodes, the first insulating layer to form a pattern including first insulating structures of the thin film transistors;
   patterning, after forming the first insulating structures, the semiconductor layer to form a pattern including active layers of the thin film transistors; and
   forming, after forming the active layers, bridge structures, and each bridge structure electrically connecting the gate electrodes of the thin film transistors in adjacent pixel units in the same first pixel unit group.

In some implementations, the method further includes: forming first gaps between the gate electrodes of the thin film transistors in the pixel units of the same first pixel unit group whiling forming the gate electrodes of the thin film transistors;

forming second gaps between the first insulating structures of the thin film transistors in the pixel units of the same first pixel unit group while forming the first insulating structures; and
forming third gaps between the active layers of the thin film transistors in the pixel units of the same first pixel unit group while forming the active layers; where
the first gaps, the second gaps and the third gaps are correspondingly arranged.

In some implementations, each of the first gaps has a width ranging from 2.5 μm to 4 μm.

In some implementations, the patterning the first insulating layer to form the pattern including the first insulating structures of the thin film transistors includes:
for each thin film transistor, patterning, by taking the gate electrode of the thin film transistor as a mask plate, the first insulating layer to form a pattern including the first insulating structure of the thin film transistor.

In some implementations, the method of claim further includes: after forming the gate electrodes and before forming the bridge structures,
forming a second insulating layer on the base substrate on which the gate electrodes are formed; and
patterning the second insulating layer to form a second insulating structure with first via holes, where each bridge structure is electrically connected with the gate electrodes of the thin film transistors in two adjacent pixel units in the same first pixel unit group through two of the first via holes, respectively.

In some implementations, an area of an orthographic projection of each first via hole on the gate electrode ranges from 16 μm² to 36 μm².

In some implementations, a minimum pitch between a boundary of an orthographic projection of each of the first via holes on the gate electrode and a boundary of the gate electrode ranges from 6 μm to 12 μm.

In some implementations, the active layer at least includes a source contact region, a drain contact region, and a channel region sandwiched between the source contact region and the drain contact region, and the method further includes:
converting, after forming the active layer, the source contact region and the drain contact region into conductors to form a source electrode and a drain electrode;
forming a pattern including second insulating structures on the base substrate on which the gate electrodes are formed through a patterning process, the second insulating structure covers the source electrode, the drain electrode and the gate electrode; and
forming a pattern including the bridge structures and data lines on a side of the second insulating structure away from the base substrate by a single patterning process, where each bridge structure is electrically connected with the gate electrodes of two adjacent thin film transistors in the same first pixel unit group through two first via holes penetrating through the second insulating structures, and each data line is electrically connected with the source electrode through a second via hole penetrating through the second insulating structure.

In some implementations, the method further includes: after forming each thin film transistor,
forming a pattern including a third insulating structure on the base substrate on which the gate electrodes are formed by a patterning process;
forming a pattern including a common electrode on a side of the third insulating structure away from the base substrate by a patterning process;
forming a pattern including a fourth insulating structure on a side of the common electrode away from the base substrate by a patterning process; and
forming a pattern including a pixel electrode on a side of the fourth insulating structure away from the base substrate by a patterning process; where
the pixel electrode is electrically connected with a drain electrode of the thin film transistor through a connection via hole penetrating through the third insulating structure and the fourth insulating structure.

In some implementations, the method further includes: before forming the buffer layer,
forming a pattern including shielding layers corresponding to the thin film transistors one by one on the base substrate by a patterning process, where
an orthographic projection of the light shielding layer corresponding to each thin film transistor on the base substrate covers an orthographic projection of a channel region of the active layer of the thin film transistor on the base substrate.

### BRIEF DESCRIPTION OF DRAWINGS

FIGS. 1a and 1b are Scanning Electron Microscope (SEM) images showing an abnormal buffer layer during manufacturing a display substrate in the related art;

FIG. 2 is a schematic structural diagram of an exemplary display substrate according to an embodiment of the present disclosure;

FIGS. 3a to 3v are schematic flow charts illustrating a method for manufacturing an exemplary display substrate according to an embodiment of the present disclosure;

FIG. 4 is a schematic diagram of a display substrate according to an embodiment of the present disclosure;

FIG. 5 shows a measured characteristic curve of a TFT with a gate insulating layer made of a high-temperature film material according to an embodiment of the present disclosure; and

FIG. 6 shows a measured characteristic curve of a TFT with a gate insulating layer made of a low-temperature film material according to an embodiment of the present disclosure.

The reference numbers are as follows: 1, a base substrate; 01, a pixel unit; 2, a light shielding layer; 3, a buffer layer; 4, a semiconductor layer; 04, an active layer; 041, a source contact region; 042, a drain contact region; 043, a channel region; 5, a first insulating layer; 05, a first insulating structure; 6, a first conductive layer; 06, a gate electrode; 71, a source electrode; 72, a drain electrode; 08, a second insulating structure; 081, a first via hole; 082, a second via hole; 9, a bridge structure; 10, a data line; via1, a first connection via hole; via2, a first sub-via hole; via3, a second sub-via hole; via4, a third connection via hole; 11, a first insulating sub-structure; 12, a second insulating sub-structure; 13, a common electrode; 14, a fourth insulating structure; 15, a pixel electrode; and 16, a pixel region.

### DETAIL DESCRIPTION OF EMBODIMENTS

To make the objects, technical solutions and advantages of the embodiments of the present disclosure more apparent, the technical solutions in the embodiments of the present disclosure will be described clearly and completely with reference to the drawings in the embodiments of the present disclosure, and it is obvious that the described embodiments are only a part of the embodiments of the present disclosure, not all of the embodiments. The components of the embodiments of the present disclosure, as generally described and illustrated in the drawings herein, could be arranged and designed in a wide variety of different configurations. Thus, the following detailed description of the embodiments of the present disclosure, provided in the accompanying drawings, is not intended to limit the scope of the present disclosure, as claimed, but is merely representative of selected embodiments of the present disclosure. All other embodiments, which can be derived by a person skilled in the art from the embodiments of the present disclosure without making any creative effort, shall fall within the protection scope of the present disclosure.

Unless defined otherwise, technical or scientific terms used herein shall have the ordinary meaning as understood by those skilled in the art to which the present disclosure belongs. The use of “first”, “second”, and the like in the present disclosure is not intended to indicate any order, quantity, or importance, but rather is used to distinguish one element from another. Also, the use of the terms “a”, “an”, “the” or similar referents do not denote a limitation of quantity, but rather denote the presence of at least one. The word “comprising/including” or “comprises/includes”, and the like, means that the element or item preceding the word includes the element or item listed after the word and its equivalent, but does not exclude other elements or items. The terms “connected/connecting” or “coupled/coupling” and the like are not restricted to physical or mechanical connections, but may include electrical connections, whether direct or indirect. The word “upper”, “lower”, “left”, “right”, and the like are used only to indicate relative positional relationships, and when the absolute position of the object being described is changed, the relative positional relationships may also be changed accordingly.

Reference to “a plurality of or a number of” in the present disclosure means two or more. “And/or” describes the association relationship of the associated objects, indicating that there may be three relationships, for example, A and/or B may indicate: A exists alone, A and B exist simultaneously, and B exists alone. The character “/” generally indicates that the former and latter associated objects are in an “or” relationship.

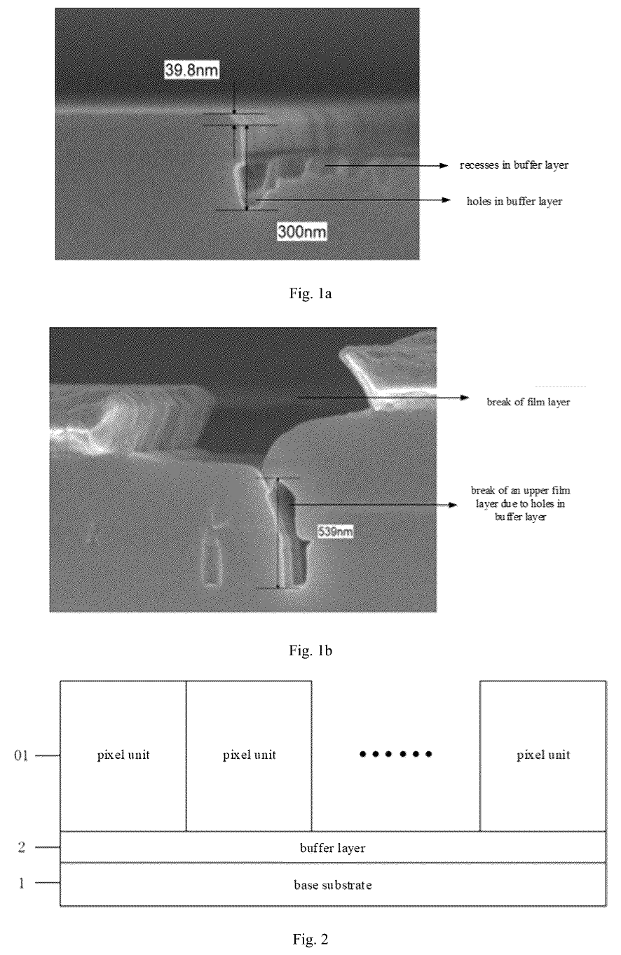

In the related art, the thin film transistor with the bottom gate structure mainly has the following two problems. On one hand, it is difficult to control the Back Channel Etching (BCE), so that the BCE easily causes over etching to affect the channel device, and thus affects the performance of the device. Although the effect of over etching can be overcome by providing an Etching Stop layer (ES), the use of the etching stop layer increases the complexity of the process. On the other hand, the bottom gate structure is not easy to realize self-alignment, and compared with a solution in which the top gate structure directly utilizes a gate electrode 06 as a mask to realize self-alignment etching, it is necessary to separately prepare a mask for the bottom gate structure to etch semiconductor film structure, however, a problem exists in the compatibility between a back exposure technology and a traditional preparation process, and the traditional preparation process may cause a relatively large overlapping area (namely, overlapping between an active layer 04 and a data line 10 and the like) in the bottom gate thin film transistor, so that a relatively large overlapping capacitance is generated, the relatively large overlapping capacitance may reduce the working speed of a driving circuit, and the bottom gate thin film transistor is difficult to be used for driving a high-resolution display, such as a Liquid Crystal Display (LCD), an active matrix organic light emitting diode display (AMOLED), and a mini/micro-LED display (MLED) which have a high-resolution and a high-refresh-rate. Therefore, more and more display products adopt the top gate type thin film transistors. However, during forming a buffer layer 3 in the display substrate having the top gate type thin film transistors, in the conventional manufacturing process, a pattern including an active layer 04 is formed through a patterning process, and then a pattern including a gate insulating layer is formed on the buffer layer 3 on which the active layer 04 is formed through another patterning process. The gate insulating layer of the top gate type thin film transistor is in direct contact with the active layer 04, if the gate insulating layer is made of a high-temperature film material, excessive hydrogen ions are injected into a semiconductor layer 4 to cause characteristic of the thin film transistor (TFT) to drift, therefore, the gate insulating layer is generally made of a low-temperature film material, the low-temperature film material has a small influence on the characteristics of the TFT, but the low-temperature film material has poor stability, as shown in FIG. 1a, recesses and holes are generated in the buffer layer 3 in the process of etching to form the gate insulating layer, and therefore film layers located thereon are prone to fracture, as shown in FIG. 1b, the coverage of the subsequent film layers are influenced, and the product yield is low.

In view of above, the present disclosure provides a display substrate and a method for manufacturing the display substrate, which substantially eliminate one or more of the problems due to limitations and disadvantages of the related art. The method for manufacturing the display substrate specifically includes the following steps: providing a base substrate 1, forming a buffer layer 3 on the base substrate 1, and forming a plurality of pixel units 01 on a side of the buffer layer 3 away from the base substrate 1. The step of forming the pixel units 01 at least includes: forming a thin film transistor of each pixel unit on a side of the buffer layer 3 away from the base substrate 1. The step of forming the thin film transistor in each pixel unit 01 includes: sequentially forming a semiconductor layer 4, a first insulating layer 5 and a first conductive layer 6 on a side of the buffer layer 3 away from the base substrate 1; patterning the first conductive layer 6 to form a pattern including a gate electrode 06 of each thin film transistor; after forming the gate electrode 06, patterning the first insulating layer 5 to form a pattern including a first insulating structure 05 of the thin film transistor; after forming the first insulating structure 05, patterning the semiconductor layer 4 to form a pattern including an active layer 04 of the thin film transistor; after forming the active layer 04, forming a bridge structure 9, the bridge structure 9 electrically connecting the gate electrodes 06 of the thin film transistors in every two adjacent pixel units 01 in a same first pixel unit group.

In the embodiment of the present disclosure, the semiconductor layer 4, the first insulating layer 5 and the first conducting layer 6 are sequentially formed on the buffer layer 3, thereafter, the semiconductor layer 4 serves as an etching stop layer for etching the first insulating layer 5, so that the problem of poor uniformity caused by etching the whole surface of the first insulating layer 5 can be effectively eliminated, simultaneously, the problem of recesses and holes in the buffer layer 3 can be effectively eliminated, compared with the method in the related art that the active layer 04 is formed first, and then the first insulating structure 05 (i.e., the gate insulating layer) is formed, the embodiment of the present disclosure can effectively eliminate the problem of recesses and holes in the buffer layer 3 without adding a mask, therefore, the product yield and dependability are improved. In addition, the active layers of the thin film transistors are independent of each other, in the above-mentioned manufacturing process of the present disclosure, it is necessary to ensure that the gate electrodes of the thin film transistors are disconnected from each other when the independent active layers of the thin film transistors are formed by etching, and after the active layers are formed, the bridge structures 9 each for electrically connecting the gate electrodes 06 of two adjacent thin film transistors in the same first pixel unit group are formed, and it is unnecessary to separately provide a signal transmission line for each gate electrode 06, therefore, the wiring complexity of a gate driving circuit can be reduced, the process efficiency can be improved, and the process cost can be reduced.

Specific steps of the method for manufacturing the display substrate provided in the embodiment of the present disclosure are described in detail below. FIG. 2 is a schematic structural diagram of an exemplary display substrate provided in an embodiment of the present disclosure, and as shown in FIG. 2, a process for manufacturing the display substrate is as follows. Firstly, a base substrate 1 is provided, and a buffer layer 3 is formed on the base substrate 1 to block diffusion of impurities, in order to prevent an active layer 04 in a top gate type thin film transistor from being affected by impurities in the base substrate 1. Then, a plurality of pixel units 01 are formed on a side of the buffer layer 3 away from the base substrate 1. The step of forming the pixel units 01 at least includes: forming thin film transistors on the side of the buffer layer 3 away from the base substrate 1. Each pixel unit 01 at least includes one of the thin film transistors.

The step of forming the thin film transistors in the pixel units 01 includes: sequentially forming a semiconductor layer 4, a first insulating layer 5 and a first conductive layer 6 on a side of the buffer layer 3 away from the base substrate 1; patterning the first conductive layer 6 to form a pattern including gate electrodes 06 of the thin film transistors; after forming the gate electrodes 06, patterning the first insulating layer 5 to form a pattern including first insulating structures 05 of the respective thin film transistors; after forming the first insulating structures 05, patterning the semiconductor layer 4 to form a pattern including active layers 04 of the thin film transistors; after forming the active layers 04, forming bridge structures 9, the bridge structures 9 each electrically connecting the gate electrodes 06 of the thin film transistors in two adjacent pixel units 01 in a same first pixel unit group.

It should be noted that the formation of the semiconductor layer 4, the insulating layer, the conductive layer, and the like described in the present disclosure means the formation of a whole material layer for the semiconductor layer 4, the insulating layer, the conductive layer, and the like, without including the patterns formed after etching the semiconductor layer 4, the insulating layer, the conductive layer, and the like.

Illustratively, the material of the semiconductor layer 4 may include, but is not limited to, any one of indium tin oxide (ITO), aluminum zinc oxide (AZO), indium zinc oxide (IZO), indium gallium zinc oxide (IGZO), indium gallium zinc tin oxide (IGZTO), indium gallium oxide (IGO), lanthanide-doped metal oxide (Ln-IGZO/IGZTO). The indium gallium zinc oxide (IGZO) may include amorphous indium gallium zinc oxide (a-IGZO), crystalline indium gallium zinc oxide, and the like. The material of the first insulating layer 5 may include, but is not limited to, one of silicon oxide (SiOx, x>0) or silicon nitride (SiNy, y>0), silicon oxynitride (SiOxNy, x>0, y>0), or a combination of more of them, and a structure of the first insulating layer 5 may be of a single layer structure or a stacked layer structure, for example, the first insulating layer 5 may be of a single layer structure of silicon oxide or silicon nitride, or a stacked layer structure alternatively staked by silicon oxide or silicon nitride. The material of first conductive layer 6 may include, but is not limited to, one of titanium (Ti), copper (Cu), molybdenum niobium (MoNb), or molybdenum nickel titanium alloy (MTD), or a combination of more of them. The bridge structure 9 is of a metal structure, and the material thereof may be the same as the metal material of a source electrode 71. For example, the material of the bridge structure 9 may include, but is not limited to, one of Ti, Cu, Mo—Nb, or MTD, or a combination of more of them.

The first conductive layer 6, the first insulating layer 5, or the semiconductor layer 4 may be patterned by, for example, a mask plate process. The first insulating structure 05 in the embodiment of the present disclosure may be understood as a gate insulating layer of the thin film transistor, which is used to isolate the gate electrode 06 from the active layer 04 to avoid a short circuit.

For example, the patterning the first conductive layer 6 may be performed as follows. For example, firstly, a photoresist is coated on the first conductive layer 6, and then the photoresist is exposed by using a mask plate M. The mask plate includes a light-transmitting area and a non-light-transmitting area, during the exposure process, a part of the photoresist corresponding to the light-transmitting area is completely exposed, and a part of the photoresist corresponding to the non-light-transmitting area is not exposed. Next, the exposed photoresist is developed to obtain a photoresist pattern, where the photoresist pattern includes a reserved area corresponding to the light-transmitting area and an area to be removed corresponding to the non-light-transmitting area. Then, the first conductive layer 6 is etched by using the photoresist pattern, for example, a part to be removed of the first conductive layer 6 is completely etched out by using a wet etching process. Finally, the residual photoresist is stripped to form a pattern including the gate electrodes 06 of the thin film transistors, where each thin film transistor includes a corresponding gate electrode 06.

For example, the patterning the first insulating layer 5 may be performed as follows. For example, a photoresist may be coated on the first insulating layer 5 and exposed by using a mask plate M. The mask plate includes a light-transmitting area and a non-light-transmitting area, during the exposure process, a part of the photoresist corresponding to the light-transmitting area is completely exposed, and a part of the photoresist corresponding to the non-light-transmitting area is not exposed. Next, the exposed photoresist is developed to obtain a photoresist pattern, where the photoresist pattern includes a reserved area corresponding to the light-transmitting area and an area to be removed corresponding to the non-light-transmitting area. Then, the first insulating layer 5 is etched by using the photoresist pattern, for example, a part to be removed of the first insulating layer 5 is completely etched out by using a dry etching process. Finally, the residual photoresist is stripped to form a pattern including the first insulating structures 05 of the thin film transistors, where each thin film transistor includes a corresponding first insulating structure 05.

For example, the patterning the semiconductor layer 4 may be performed as follows. For example, a photoresist is coated on a side of the first insulating structures 05 of the thin film transistors, away from the base substrate 1, and the photoresist is exposed by using a mask plate M. Similar to the exposure mode of the first insulating layer 5, the mask plate includes a light-transmitting area and a non-light-transmitting area, during the exposure process, a part of the photoresist corresponding to the light-transmitting area is completely exposed, and a part of the photoresist corresponding to the non-light-transmitting area is not exposed. Next, the exposed photoresist is developed to obtain a photoresist pattern, where the photoresist pattern includes a reserved area corresponding to the light-transmitting area and an area to be removed corresponding to the non-light-transmitting area. Then, the semiconductor layer 4 is etched by using the photoresist pattern, for example, a region to be removed of the semiconductor layer 4 is completely etched out by using a wet etching process. Finally, the residual photoresist is stripped to form a pattern including the active layers 04 of the thin film transistors, where each thin film transistor includes a corresponding active layer 04.

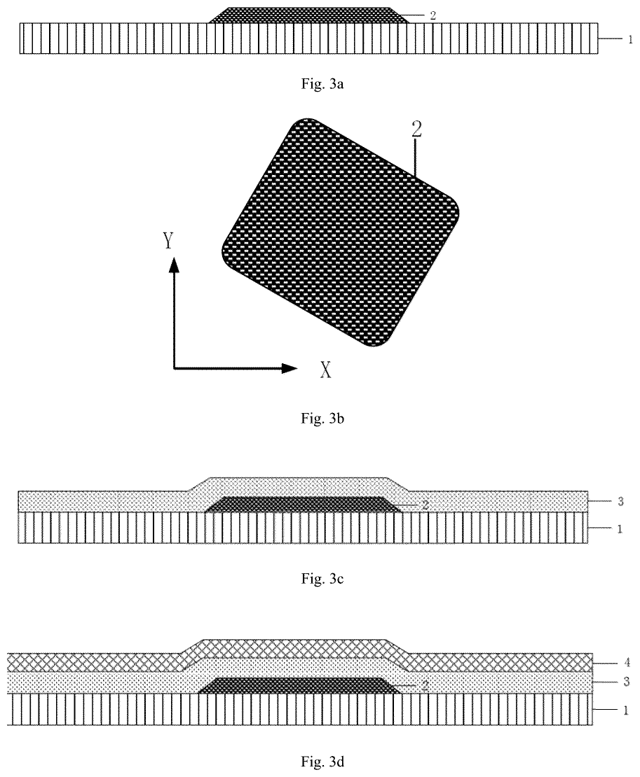

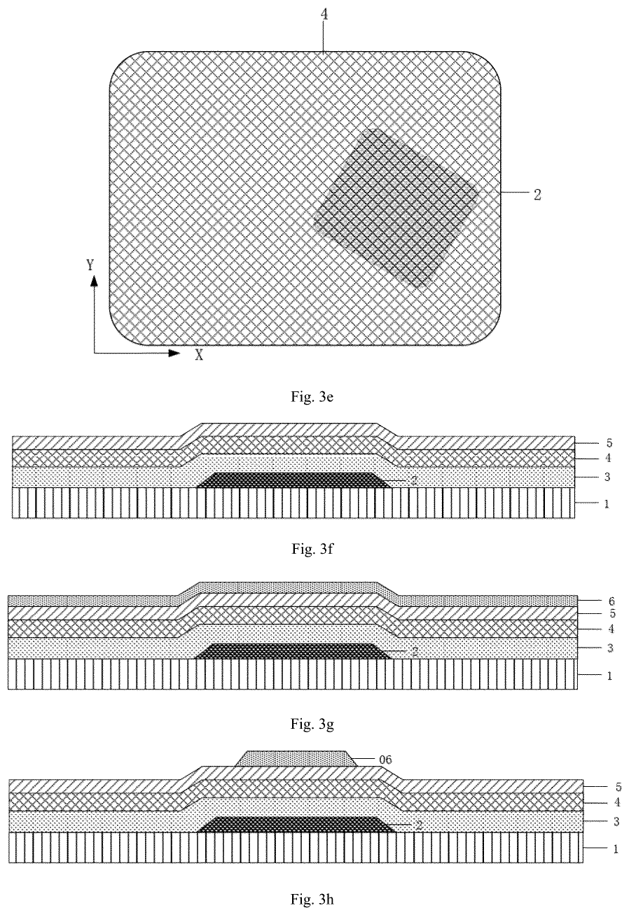

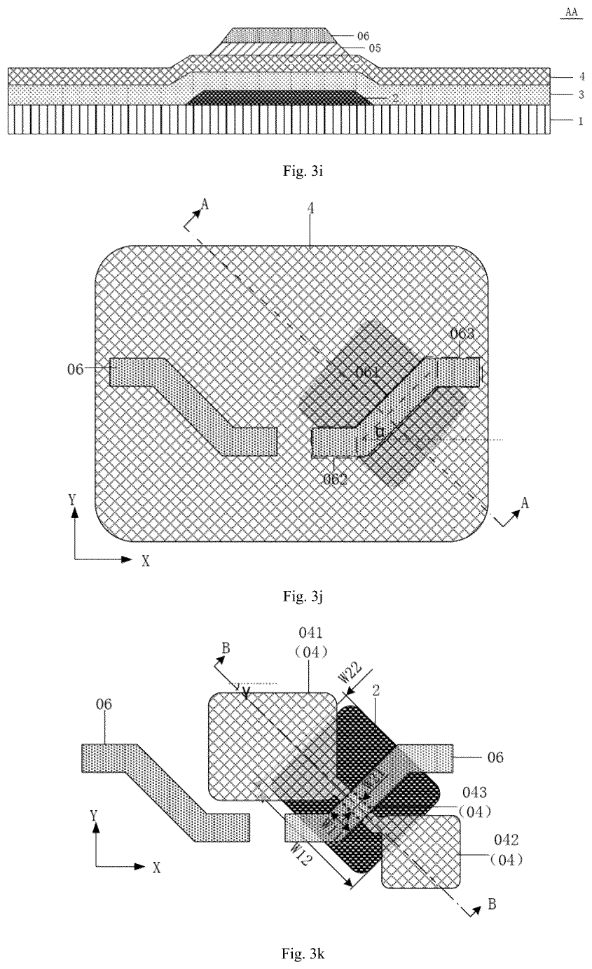

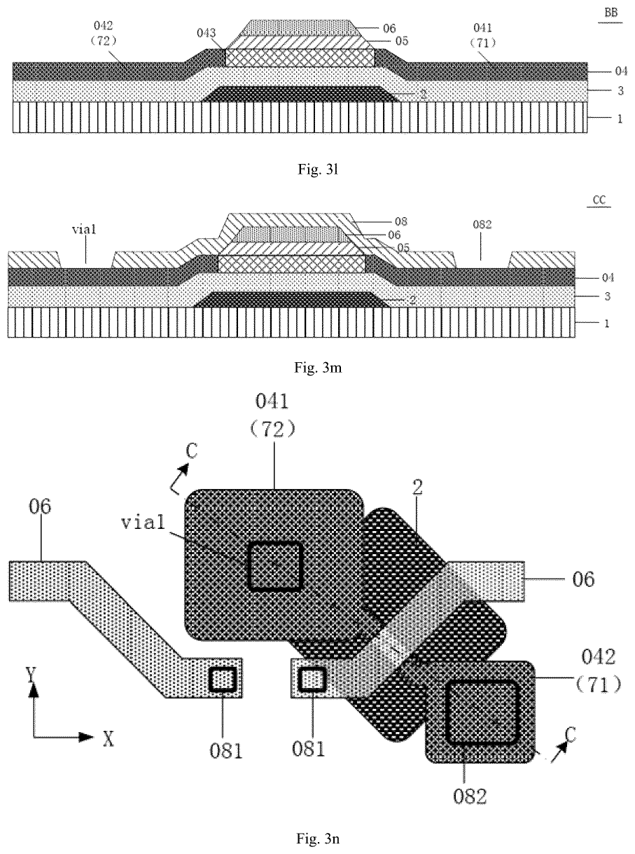

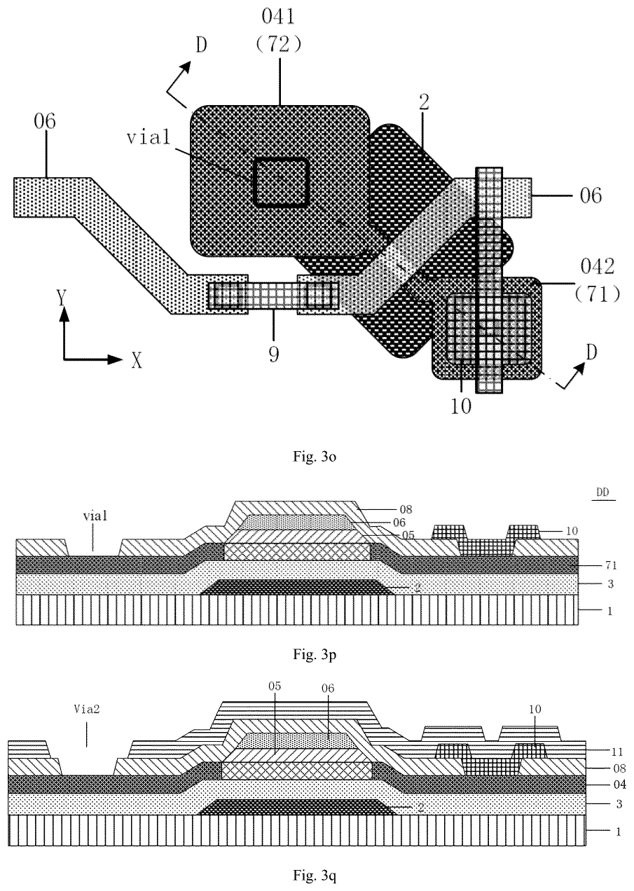

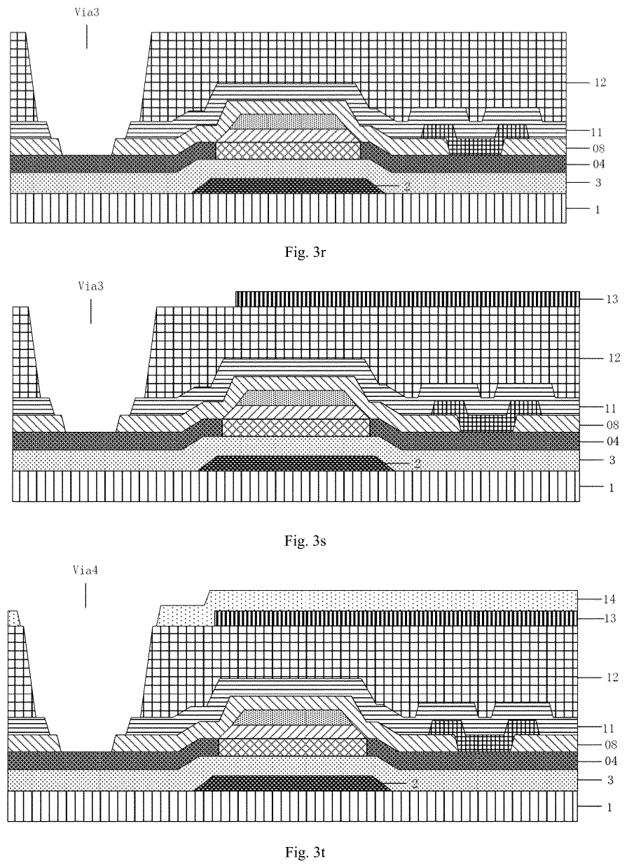

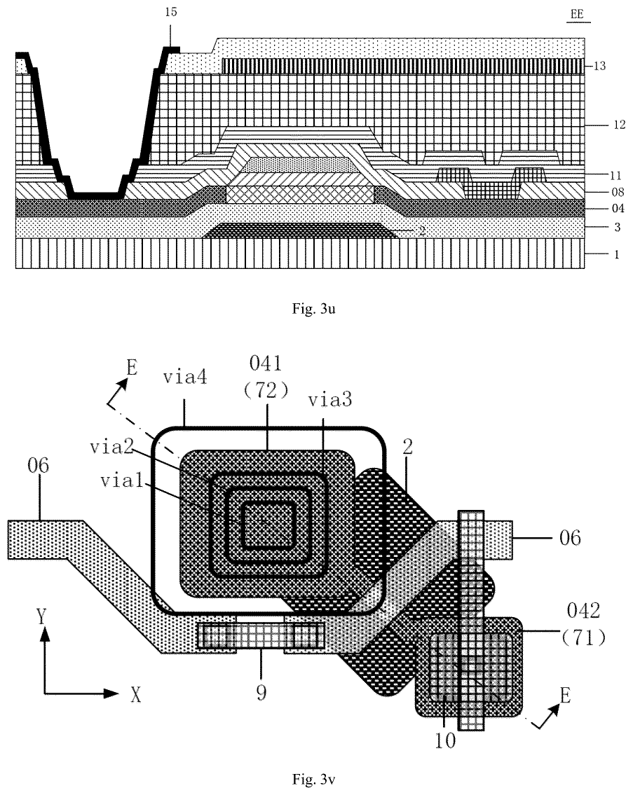

FIGS. 3a to 3v are schematic flow charts illustrating a method for manufacturing an exemplary display substrate according to an embodiment of the present disclosure, and specific manufacturing processes of the following embodiments are shown in FIGS. 3a to 3v.

In some implementations, in order to ensure that the active layer 04 of the thin film transistor is not affected by ambient light, as shown in FIGS. 3a and 3b, where FIG. 3b is a top view of the light shielding layer 2 in FIG. 3a, before the buffer layer 3 is formed, the method further includes: forming a pattern, including light shielding layers 2 corresponding to the thin film transistors one by one, on the base substrate 1 through a patterning process. An orthographic projection of the light shielding layer 2 corresponding to each thin film transistor on the base substrate 1 covers an orthographic projection of a channel region 043 of the active layer 04 of the thin film transistor on the base substrate 1.

Illustratively, a material of the light shielding layer 2 may include, but is not limited to, one of Ti, Cu, MoNb and MTD, or a combination of more of them.

As shown in FIG. 3c, the buffer layer 3 is formed on a side of the light shielding layers 2 of the thin film transistors away from the base substrate 1.

As shown in FIGS. 3d and 3e, where FIG. 3e is a top view of the semiconductor layer 4 in FIG. 3d. The semiconductor layer 4 is formed on a side of the buffer layer 3 away from the base substrate 1.

As shown in FIG. 3f, the first insulating layer 5 is formed on a side of the semiconductor layer 4 away from the base substrate 1.

In some implementations, the step of forming the thin film transistor in each pixel unit 01 further includes: forming the gate electrode 06 of each thin film transistor on a side of the first insulating structure 05 away from the base substrate 1.

In one case, the gate electrode 06 of each thin film transistor is formed before the first insulating structure 05 of the thin film transistor is formed. Specifically, as shown in FIG. 3g, the first conductive layer 6 is formed on a side of the first insulating layer 5 away from the semiconductor layer 4; as shown in FIG. 3h, the first conductive layer 6 is patterned to form a pattern including the gate electrode 06 of each thin film transistor. Here, in the embodiment of the present disclosure, the semiconductor layer 4, the first insulating layer 5, and the first conductive layer 6 are sequentially formed on the base substrate 1. Thereafter, as shown in FIG. 3h, the first conductive layer 6 is patterned to form a pattern including the gate electrodes 06 of the thin film transistors; then, as shown in FIG. 3i and FIG. 3j, where FIG. 3j is a top view of a part of the film layer structure in FIG. 3i, the first insulating layer 5 is patterned to form a pattern including the first insulating structures 05 of the thin film transistors; thereafter, as shown in FIGS. 3k and 3l, the semiconductor layer 4 is patterned to form a pattern including the active layers 04 of the thin film transistors.

Alternatively, for any one of the thin film transistors, the first insulating layer 5 may be patterned by using the gate electrode 06 of the thin film transistor as a mask plate, to form a pattern including the first insulating structure 05 of the thin film transistor, as shown in FIGS. 3i and 3j. Here, a top gate self-alignment manner is adopted, for each thin film transistor, after the gate electrode 06 is manufactured, the gate electrode 06 of the thin film transistor is used as a mask plate in the manufacturing process of the first insulating structure 05 of the thin film transistor, and compared with a manner that the mask plates for forming the gate electrodes and the gate insulating layers need to be provided separately in the related art, the embodiment of the present disclosure can reduce the cost of the mask plate used for manufacturing the first insulating structures 05, and the top gate self-alignment manner is adopted, so that the process complexity is simplified, and the manufacturing efficiency is improved.

In another case, after the active layer 04 is formed, the gate electrodes 06 of the thin film transistors are formed. Specifically, after the semiconductor layer 4 is patterned to form a pattern including the active layers 04 of the thin film transistors, the first conductive layer 6 is formed on the base substrate 1 on which the active layer 04 and the first insulating layer 5 are formed, and patterning is performed on the first conductive layer 6 to form a pattern including the gate electrodes 06 of the thin film transistors according to the above-described patterning process. Here, after the active layer 04 is formed, the formed gate electrodes 06 of the respective thin film transistors may be directly electrically connected to each other, reducing the wiring complexity of the gate driving circuit. Compared with the mode of firstly forming the gate electrodes 06 and then forming the active layers 04, no bridge structure 9 is required to be formed, the wiring complexity of the gate driving circuit is further reduced, the process efficiency is improved, and the process cost is reduced.

In some implementations, taking the sequential formation of the gate electrodes 06, the first insulating structures 05 and the active layers 04 as an example, due to the limitation of the manufacturing sequence of the process, in order to avoid the short circuit of the thin film transistors located in the adjacent pixel units 01 in the same first pixel unit group and to avoid the connection of the active layers 04 of the adjacent thin film transistors located in the same first pixel unit group, the active layers 04 of the adjacent thin film transistors need to be disconnected from each other. Due to the limitation of the manufacturing sequence of the process, the active layers 04 are correspondingly located below the formed gate electrodes 06, in order to avoid short circuit of the thin film transistors, the gate electrodes 06 of the adjacent thin film transistors in the same first pixel unit group are disconnected from each other, and specifically, a first gap may be formed between the gate electrodes 06 of the thin film transistors in every two adjacent pixel units 01 of the same first pixel unit group while the gate electrodes 06 of the thin film transistors are formed, the first gaps disconnecting the gate electrodes 06 of the thin film transistors from each other.

While forming the first insulating structures 05, a second gap is formed between the first insulating structures 05 of the respective thin film transistors in every two adjacent pixel units 01 in the same first pixel unit group. Here, the first insulating structures 05 of the thin film transistors may be formed by using a top gate self-aligned etching, and then, while the first insulating structures 05 are formed, the second gap is automatically formed between the first insulating structures 05 of the respective thin film transistors in every two adjacent pixel units 01 in the same first pixel unit group, the second gaps being disposed corresponding to the first gaps.

While forming the active layers 04, a third gap is formed between the active layers 04 of the respective thin film transistors in every two adjacent pixel units 01 in the same first pixel unit group. Here, in order to avoid short circuit between the thin film transistors, while the active layer 04 is formed by patterning using the mask plate M, the active layers 04 of the thin film transistors in the pixel units 01 in the same first pixel unit group are directly disconnected from each other to form the third gaps. The third gaps are arranged corresponding to the second gaps. Meanwhile, the first gaps, the second gaps and the third gaps are correspondingly arranged.

In some implementations, each first gap has a width ranging from 2.5 μm to 4 μm. A width of each second gap is less than or equal to the width of the first gap, and a width of each third gap is less than or equal to the width of the second gap. The width of the third gap may range from 2.5 μm to 4 μm to enable disconnection between the active layers 04. Based on this, in the case of satisfying the disconnection between the active layers 04 of the thin film transistors in the pixel units 01 in the same first pixel unit group, the width of the third gap may be any specific value in the range from 2.5 μm to 4 μm.

Alternatively, as shown in FIG. 3m to FIG. 3n, where FIG. 3n is a top view of a part of the film layer structure in FIG. 3m, for clarity of the description of the film layers in the present disclosure, a second insulating structure 08 is not shown in FIG. 3n, and a first via hole 081 in the second insulating structure 08 is represented by a solid-line frame. After forming the gate electrodes 06, and before forming the bridge structures 9, the method for manufacturing the display substrate further includes: forming a second insulating layer on the base substrate 1 on which the gate electrodes 06 are formed; patterning the second insulating layer to form the second insulating structure 08 having first via holes 081 therein; each bridge structure 9 is electrically connected to the gate electrodes 06 of the thin film transistors in two adjacent pixel units in the same first pixel unit group through two first via holes 081.

Here, the second insulating layer is a whole material layer, without including a pattern formed after etching. A material of the second insulating layer may include, but is not limited to, one of silicon oxide or silicon nitride, or a combination of more of them.

For example, the second insulating layer may be patterned by using a mask plate M. The second insulating structure 08 in the embodiment of the present disclosure may be understood as an interlayer insulating layer for covering the gate electrodes 06 and the active layers 04.

For example, patterning the second insulating layer may be performed as follows. For example, a photoresist may be coated on the second insulating layer, and the photoresist may be exposed by using the mask plate M. The mask plate includes a light-transmitting area and a non-light-transmitting area, during the exposure process, a part of the photoresist corresponding to the light-transmitting area is completely exposed, and a part of the photoresist corresponding to the non-light-transmitting area is not exposed. Next, the exposed photoresist is developed to obtain a photoresist pattern, where the photoresist pattern includes a reserved area corresponding to the light-transmitting area and an area to be removed corresponding to the non-light-transmitting area. Then, the second insulating layer is etched by using the photoresist pattern, for example, a region to be removed of the second insulating layer is completely etched out by using a dry etching process. Finally, the residual photoresist is stripped to form a pattern including the second insulating structure 08.

As shown in FIG. 30, a plurality of bridge structures 9 are formed on a side of the second insulating structure 08 away from the base substrate 1, where each bridge structure 9 is electrically connected to the gate electrodes 06 of two adjacent thin film transistors in the same first pixel unit group through two first via holes 081.

In some implementations, an area of an orthographic projection of the first via hole 081 on the gate electrode 06 ranges from 16 μm² to 36 μm². In some implementations, dimensions of the orthographic projection of the first via hole 081 on the gate electrode 06 may be 4 μm×4 μm, and in a case that the orthographic projection of the first via hole 081 on the base substrate 1 does not exceed an orthographic projection of the gate electrode 06 on the base substrate 1, the dimensions of the orthographic projection of the first via hole 081 on the gate electrode 06 is set to 4 μm×4 μm, which can ensure that the bridge structure 9 is relatively stably electrically connected with the gate electrodes 06 through the first via holes 081.

In some implementations, in order to avoid disconnection between the bridge structure 9 and the gate electrodes 06, a minimum pitch between a boundary of the orthographic projection of the first via hole 081 on the gate electrode 06 and a boundary of the gate electrode 06 ranges from 6 μm to 12 μm, so as to ensure that the bridge structure 9 is relatively stably electrically connected with the gate electrodes 06 through the first via holes 081.

In some implementations, a depth of the first via hole 081 is the same as a thickness of the second insulating structure 08, and the thickness of the second insulating structure 08 ranges from 3000 Å to 5000 Å, that is, the depth of the first via hole 081 ranges from 3000 Å to 5000 Å.

In some implementations, the active layer 04 includes at least a source contact region 041, a drain contact region 042, and a channel region 043 sandwiched between the source contact region 041 and the drain contact region 042. After the active layer 04 is formed, the method for manufacturing the display substrate further includes the following steps.

As shown in FIG. 3l, before the second insulating layer is formed, the source contact region 041 and the drain contact region 042 are conducted (that is, they are converted into conductors) to form a source electrode 71 and a drain electrode 72. For example, the source contact region 041 and the drain contact region 042 may be conducted by performing plasma injection or plasma treatment thereon, so as to form an ohmic contact, that is, the conducted source contact region 041 in the active layer 04 is the source electrode 71, and the conducted drain contact region 042 in the active layer 04 is the drain electrode 72. The source contact region 041 and the drain contact region 042 may be conducted by doping n-type impurities or p-type impurities into the source contact region 041 and the drain contact region 042.

As shown in FIG. 3m, on the base substrate 1 on which the gate electrode 06 is formed, the pattern including the second insulating structure 08 is formed by a patterning process, the second insulating structure 08 covers the source electrode 71, the drain electrode 72 and the gate electrode 06. Here, a specific process of forming the pattern including the second insulating structure 08 by a patterning process may refer to the specific process of forming the second insulating structure 08 described above, where the patterning process includes processes of depositing a thin film (the second insulating layer) and patterning, and repeated description thereof is omitted.

As shown in FIG. 3n, the first via holes 081 and a second via hole 082 are formed simultaneously with the formation of the pattern including the second insulating structure 08. The first via holes 081 each expose the gate electrode 06; and the second via hole 082 exposes the source contact region 041 of the active layer 04, i.e., the source electrode 71.

As shown in FIG. 30 and FIG. 3p, a pattern including the bridge structure 9 and a data line 10 located on a side of the second insulating structure 08 away from the base substrate 1 is formed by a single patterning process, the bridge structure 9 is electrically connected to the gate electrodes 06 of two adjacent thin film transistors in the same first pixel unit group through two first via holes 081 penetrating through the second insulating structure 08, and the data line 10 is electrically connected to the source electrode 71 through the second via hole 082 penetrating through the second insulating structure 08. It should be understood that the data line 10 may be connected to an external driving circuit through a via hole penetrating through the insulating layer, and as for other film layer structures other than the second insulating structure 08 through which the data line 10 penetrates, the description thereof is not given in the present disclosure.

Here, the bridge structure 9 and the data line 10 may be made of the same material, for example, they are made of the same metal material as the source electrode 71, where the metal material may include, but is not limited to, one of Ti, Cu, MoNb, or MTD, or a combination of more of them. The metal material layer may be deposited and patterned, and the pattern including the bridge structure 9 and the data line 10 on the side of the second insulating structure 08 away from the base substrate 1 are formed at the same time, so that the process of respectively forming the bridge structure 9 and the data line 10 are omitted, and the manufacturing efficiency of the display substrate is improved.

According to the method for manufacturing the display substrate provided in the embodiments and combination thereof, the first conductive layer 6 and the first insulating layer 5 are patterned first to form the gate electrodes 06 and the first insulating structures 05, and then the semiconductor layer 4 is patterned to form the active layers 04, in this way, the appearance of the buffer layer 3 cannot be affected for the protection of the semiconductor layer 4 below the first insulating layer 5 after the first insulating layer 5 is etched, the gate electrodes 06 of adjacent TFTs are disconnected from each other simultaneously, a part of the semiconductor layer 4 below the disconnection position is guaranteed to be etched out completely, the gate electrodes 06 are bridged by the bridge structure 9 at the disconnection position, and the signal transmission is guaranteed. Therefore, the problem of recesses and holes in the buffer layer 3 caused by the dry etching of the entire surface of the first insulating layer 5 can be effectively eliminated, and the product yield is improved.

In some implementations, after forming the thin film transistors, the method for manufacturing the display substrate further includes: forming a pattern including a third insulating structure on the base substrate 1 on which the gate electrodes 06 are formed through a patterning process.

Illustratively, as shown in FIG. 3q, the third insulating structure includes a first insulating sub-structure 11 formed on the base substrate 1 with the gate electrode 06 formed thereon by a patterning process, and the first insulating sub-structure 11 may be a first passivation layer capable of preventing the thin film transistor from being corroded by moisture and oxygen. As shown in FIG. 3r, the third insulating structure further includes a second insulating sub-structure 12 formed on a side of the first insulating sub-structure 11 away from the base substrate 1 through a patterning process, and the second insulating sub-structure 12 may be a planarization layer.

Here, the patterning process includes a film deposition process and a patterning process, and the process of forming the pattern including the third insulating structure may refer to the process of forming the first insulating structure 05, and repeated description is omitted.

A material of the first insulating sub-structure 11 may include, but is not limited to, one of silicon oxide (SiOx, x>0), silicon nitride (SiNy, y>0), or silicon oxynitride (SiOxNy, x>0, y>0), or a combination of more of them. The material of the second insulating sub-structure 12 may include, but is not limited to, a resin-based polymer.

A pattern including a common electrode 13 is formed on a side of the third insulating structure away from the base substrate 1 by a patterning process. As shown in FIG. 3s, a thickness of the common electrode 13 ranges from, for example, 700 angstroms to 1000 angstroms. A material of the common electrode 13 may be indium tin oxide (ITO).

As shown in FIG. 3t, a pattern including a fourth insulating structure 14 is formed on a side of the common electrode 13 away from the base substrate 1 by a patterning process. Here, the fourth insulating structure 14 may be a second passivation layer for isolating the common electrode 13 from a pixel electrode 15 while preventing the structure encapsulated in the display substrate from being corroded by moisture and oxygen. Illustratively, the material of the fourth insulating structure 14 may include, but is not limited to, one of silicon oxide (SiOx, x>0), silicon nitride (SiNy, y>0), or silicon oxynitride (SiOxNy, x>0, y>0), or a combination of more of them.

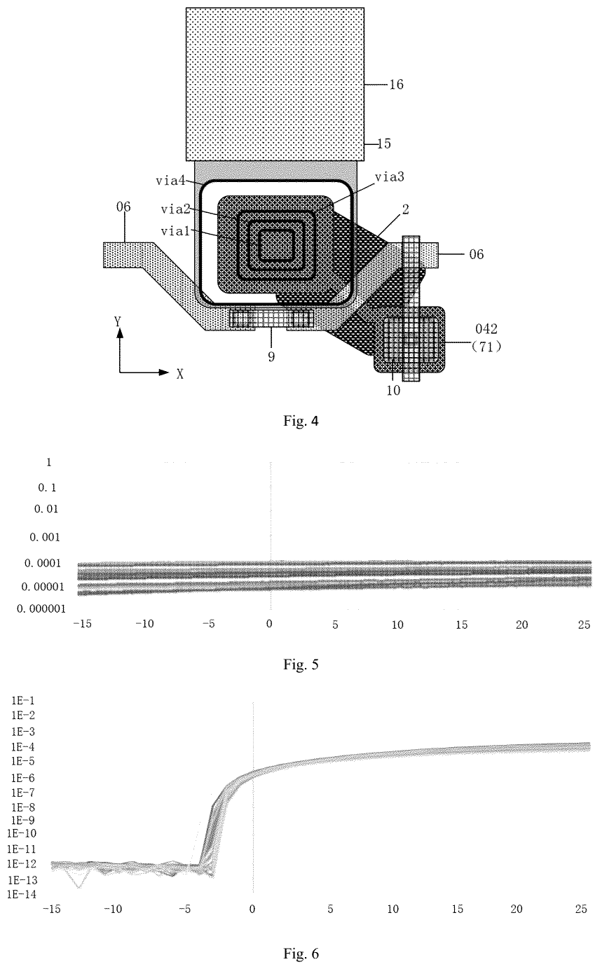

As shown in FIG. 3u, a pattern including the pixel electrode 15 is formed on a side of the fourth insulating structure 14 away from the base substrate 1 by a patterning process. The pixel electrode 15 is electrically connected to the drain electrode 72 of the thin film transistor through a connection via hole penetrating through the second insulating structure 08, the third insulating structure, and the fourth insulating structure 14. As shown in FIG. 4, the pixel in a pixel region 16 is electrically connected to the pixel electrode 15, and an external signal drives the pixel in the pixel region 16 through the thin film transistor electrically connected to the pixel electrode 15. Illustratively, a thickness of the pixel electrode 15 ranges from 700 angstroms to 1000 angstroms. A material of the pixel electrode 15 may be indium tin oxide (ITO).

In some implementations, the connection via hole has a depth ranging from 2.5 μm to 3.5 μm. As shown in FIG. 3t and FIG. 3v, FIG. 3v being a top view of a part of the film layer structure in FIG. 3t, for the sake of structural representation, the via holes in FIG. 3v are only represented by solid line frames, the film layer structures actually having the via holes are not shown, and each solid line frame is only used as a schematic representation of the via hole, and cannot be used as a limitation to the actual structure of the film layer having the via hole.

The connection via hole includes a first connection via hole via1 passing through the second insulating structure 08, a second connection via hole passing through the third insulating structure, and a third connection via hole via4 passing through the fourth insulating structure 14; outlines of orthographic projections of the first connection via hole via1, the second connection via hole and the third connection via hole via4 on the base substrate 1 are nested sequentially. In a case where the third insulating structure includes a first insulating sub-structure 11 and a second insulating sub-structure 12, the second connection via hole includes a first sub-via hole via2 penetrating through the first insulating sub-structure 11 and a second sub-via hole via3 penetrating through the second insulating sub-structure 12. Outlines of orthographic projections of the first connecting via hole via1, the first sub-via hole via2, the second sub-via hole via3, and the third connecting via hole via4 on the base substrate 1 are nested sequentially. With the arrangement of the connection via holes, the phenomenon of disconnection of the pixel electrode 15 caused by the excessively deep connection via hole while forming the pixel electrode 15 can be effectively relieved or avoided.

The method for manufacturing the display substrate of the present disclosure is described in detail below by means of a complete embodiment, the method includes steps S11 to S14.

At step S1, as shown in FIGS. 3a and 3b, a base substrate 1 is provided, and a light shielding layer 2 is formed on the base substrate 1.

At step S2, as shown in FIG. 3c, a buffer layer 3 is formed on a side of the light shielding layer 2 away from the base substrate 1.

At step S3, as shown in FIGS. 3d to 3g, a semiconductor layer 4, a first insulating layer 5 and a first conductive layer 6 are sequentially formed on a side of the buffer layer 3 away from the base substrate 1.

At step S4, as shown in FIG. 3h, the first conductive layer 6 is patterned to form a pattern including a gate electrode 06 of each thin film transistor.

At step S5, as shown in FIG. 3i, the first insulating layer 5 is patterned to form a pattern including a first insulating structure 05 of each thin film transistor.

At step S6, as shown in FIGS. 3j and 3k, the semiconductor layer 4 is patterned to form a pattern including an active layer 04 of each thin film transistor.

At step S7, as shown in FIG. 3l, a source contact region 041 and a drain contact region 042 are converted into conductor to form a source electrode 71 and a drain electrode 72.

At step S8, as shown in FIGS. 3m and 3n, a pattern including a second insulating structure 08 is formed on the base substrate 1 on which the gate electrode 06 is formed, by a patterning process. The second insulating structure 08 includes first via holes 081 and a second via hole 082.

At step S9, as shown in FIGS. 30 and 3p, a pattern including a bridge structure 9 and a data line 10 on a side of the second insulating structure 08 away from the base substrate 1 is formed by a single patterning process. The bridge structure 9 is electrically connected to gate electrodes 06 of two adjacent thin film transistors in a same first pixel unit group through two first via holes 081 penetrating through the second insulating structure 08, and the data line 10 is electrically connected to the source electrode 71 through the second via hole 082 penetrating through the second insulating structure 08.

At step S10, as shown in FIG. 3q, a pattern including a first insulating sub-structure 11 is formed on the base substrate 1 on which the gate electrode 06 is formed by a patterning process.

At step S11, as shown in FIG. 3r, a pattern including a second insulating sub-structure 12 is formed on the base substrate 1 on which the first insulating sub-structure 11 is formed by a patterning process.

At step S12, as shown in FIG. 3s, a pattern including a common electrode 13 is formed on a side of the second insulating sub-structure 12 away from the base substrate 1 by a patterning process.

At step S13, as shown in FIG. 3t, a pattern including a fourth insulating structure 14 is formed on a side of the common electrode 13 away from the base substrate 1 by a patterning process.

At step S14, as shown in FIG. 3u, a pattern including a pixel electrode 15 is formed on a side of the fourth insulating structure 14 away from the base substrate 1 by a patterning process.

In addition, an embodiment of the present disclosure further provides a display substrate which can be manufactured by adopting the above-mentioned method. FIG. 4 is a schematic diagram of a display substrate provided in an embodiment of the present disclosure, and FIG. 4 only shows a schematic diagram of film layers of one pixel unit 01, and the same is true for other pixel units 01. The display substrate includes a base substrate 1, a buffer layer 3 arranged on the base substrate 1, and a plurality of pixel units 01 arranged on a side of the buffer layer 3 away from the base substrate 1. The plurality of pixel units 01 constitute a plurality of first pixel unit groups arranged side by side in a second direction Y, and a plurality of second pixel unit groups arranged side by side in a first direction X; each of the first pixel unit groups includes a plurality of pixel units 01 arranged side by side in the first direction X, and each of the second pixel unit groups includes a plurality of pixel units 01 arranged side by side in the second direction Y. Each pixel unit 01 includes at least a thin film transistor, a gate electrode 06 of the thin film transistor is farther away from the base substrate 1 than the active layer 04 of the thin film transistor, and an orthographic projection of the active layer 04 of the thin film transistor on the base substrate 1 covers an orthographic projection of the gate electrode 06 on the base substrate 1. The gate electrodes 06 of the thin film transistors in two adjacent pixel units 01 in each first pixel unit group are electrically connected through a bridge structure 9.

Since the display substrate provided by the embodiment of the present disclosure is formed by the above-mentioned method, the gate electrodes 06 of adjacent thin film transistors are disconnected before the active layers 04, independent from each other, of the thin film transistor are formed. In the display substrate provided by the present disclosure, the gate electrodes 06 of the transistors in every two adjacent pixel units in each pixel unit group are electrically connected to each other through the bridge structure 9, it is unnecessary to providing a signal transmission line for each gate electrode 06, so that the wiring complexity of the gate driving circuit can be reduced, the process efficiency is improved, and the process cost is reduced.

In some implementations, as shown in FIG. 30, the bridge structure 9 is located between two adjacent pixel units 01 along the second direction Y.

In some implementations, as shown in FIG. 3j, the gate electrode 06 includes a body structure 061 and a first extension structure 062 and a second extension structure 063 connected to two ends of the body structure, respectively; an included angle between an extending direction in which the body structure 061 extends and the first direction X is a first included angle α ranging from 30° to 85°. Preferably, the first included angle α may range from 45° to 60°

In some implementations, as shown in FIG. 3j, the gate electrode 06 includes a body structure 061 and a first extension structure 062 and a second extension structure 063 connected to two ends of the body structure 061, respectively; the first extension structure 061 and the second extension structure 062 are oppositely directed, an included angle between an extending direction in which each of the first extension structure and the second extension structure extends and the first direction X is a second included angle ranging from 0° to 10°.

Illustratively, the extending directions in which each of the first extension structure 062 and the second extension structure 063 extend is parallel to the first direction X.

The gate electrode 06 obtained by the above embodiments and combination thereof includes the inclined body structure 061, and the first extension structure 062 and the second extension structure 063 parallel to the first direction X, and the gate electrode 06 arranged in this way is adapted to a spatial layout of the pixel units 01 in the present disclosure, so that the adjacent pixel units 01 are arranged more compact, thereby increasing the density of pixels and further increasing the resolution of the product.

In some implementations, as shown in FIG. 3k, an extending direction in which the active layer 04 extends and the first direction X form a third included angle γ ranging from 35° to 60°. Preferably, the third included angle γ may range from 40° to 45°. Herein, the extending direction in which the active layer 04 extends may be understood as the extending direction in which a body structure of the active layer 04 extends (illustrated by an extending direction in which the dashed dotted line extends in the figure). Here, the body structure of the active layer 04 is inclined for adapting to the spatial layout of the pixel units 01 in the present disclosure, so that the adjacent pixel units 01 are arranged more compact, thereby increasing the density of pixels and further increasing the resolution of the product.

In some implementations, as shown in FIG. 3k, a light shielding layer 2 is further disposed on a side of the buffer layer 3 close to the substrate 1, and an orthographic projection of the light shielding layer 2 on the base substrate 1 at least covers an orthographic projection of a channel region 043 of the active layer 01 on the base substrate 1.

In some implementations, as shown in FIG. 3k, in the extending direction in which the active layer 04 extends, a ratio of a first width W11 of the channel region 043 to a first width W12 of the light shielding layer 2 ranges from 1:7 to 1:4. For example, the first width W11 of the channel region 043 ranges from 2 μm and 4 μm, and widths of parts of the light shielding layer 2 at both sides of the channel region 043 are both 6 μm, i.e., an overall width of the light shielding layer 2 (i.e., the first width W12) ranges from 14 μm to 16 μm.

In some implementations, as shown in FIG. 3k, in a direction perpendicular to the extending direction in which the active layer 04 extends, a ratio of a second width W21 of the channel region 043 to a second width W22 of the light shielding layer 2 ranges from 1:7 to 1:4.

In some implementations, as shown in FIG. 3k, the active layer 04 includes a first portion, a second portion, and a third portion (not shown); the first portion is located at the source contact region 041 of the active layer 04. The second portion is located at the drain contact region 042 of the active layer 04. The third portion is located directly below the gate electrode 06, and specifically, an orthogonal projection of the third portion on the base substrate 1 covers an orthogonal projection of the gate electrode 06 of the thin film transistor on the base substrate 1.

Taking a case where the gate electrode 06, the first insulating structure 05 and the active layer 04 are sequentially formed as an example, it should be noted that, in a common case, the channel region 043 is located between connection ends of the first portion and the second portion, a length of the channel region 043 is equal to the width of the gate electrode 06, a width of the channel region 043 is equal to a width of each of the connection ends, connecting with the third portion, of the first portion and the second portion, as shown by a region indicated by a dashed line in FIG. 3k, the widths of the first portion and the second portion are affected by all parameters of the display substrate, and after the design is completed, the widths of the first portion and the second portion are fixed values. However, in the embodiment of the present disclosure, the active layer 04 is located under the formed gate electrode 06, that is, an orthographic projection of the third portion on the base substrate 1 covers the orthographic projection of the gate electrode 06 of the thin film transistor on the base substrate 1. After the gate electrode 06 is applied with a voltage, the active layer 04 is conducted, and on the premise that the aperture ratio is not affected, the width of the channel region 043 is increased to a certain extent, that is, in the present disclosure, the width of the channel region 043 is slightly greater than that of the region defined by the dashed line frame in FIG. 3k, so that the on-state current is increased, the response efficiency of the thin film transistor is increased, and the response efficiency of the whole display substrate is increased.

In some implementations, a material of the first insulating structure 05 is one of silicon oxide or silicon nitride, or a combination of more of them.

In some implementations, the first insulating structure 05 has a refractive index ranging from 1.45 to 1.46.

FIG. 5 shows a measured characteristic curve of a TFT with a gate insulating layer made of a high-temperature film material according to an embodiment of the present disclosure, as shown in FIG. 5, the abscissa represents a gate voltage Vgs (ranging from −15V to 25V), and the ordinate represents a gate electrode current Id. With the gate insulating layer made of the high-temperature film material, after measured, the gate voltage Vgs is in a range from −15V to 25V, the gate current is in a range from 0.000001 A to 0.0001 A, and obviously, the gate current is relatively large, which indicates that the thin film transistor is always in a turned-on state, or that the whole active layer 04 is conducted (that is, the whole active layer 04 is converted into a conductor) and loses the characteristics of the semiconductor of the active layer 04, and in this case, the requirements for the gate insulating layer (namely the first insulating structure 05) are no longer met. In view of this, in the embodiment of the present disclosure, a low-temperature film material is adopted as the material of the first insulating structure 05, and the refractive index of the first insulating structure 05 is set to be in a range from 1.45 to 1.46, which is greater than the refractive index of the material of the gate insulating layer made of the high-temperature film material. FIG. 6 shows a measured characteristic curve of a TFT with a gate insulating layer made of a low-temperature film material according to an embodiment of the present disclosure, as shown in FIG. 6, the abscissa represents a gate voltage Vgs (ranging from −15V to 25V), and the ordinate represents a gate current Id. With the gate insulating layer made of the low-temperature film material, after measured, the gate voltage Vgs is in a range from −15V to 0V, the gate current is in a range from 10⁻¹⁴ A to 10⁻⁶ A, where the gate current is about 10⁻¹² A in a case where the gate voltage Vgs is in a range from −15V to −5V, the gate current is obviously relatively small, it indicates that the thin film transistor is always in a turned-off state when the thin film transistor is not turned on. The gate current is about 10⁻⁵ A in a case where the gate voltage Vgs is in a range from 0V to 25V, the gate current is obviously relatively large, it indicates that the thin film transistor is always in a turned-on state when the thin film transistor is turned on, so that the requirement for the gate insulating layer (namely the first insulating structure 05) are met.

In the related art, the thin film transistors currently widely adopted mainly includes amorphous silicon thin film transistors and polysilicon thin film transistors. However, the mobility of amorphous silicon (a-Si) is low, typically below 1 cm²/V·S; polysilicon has poor uniformity, a complex process, high cost, sensitivity to visible light, inability to work under the irradiation of visible light, and difficulty in being used for display substrates with large-size and high-resolution.

In the embodiments of the present disclosure, the channel region 043 of the source layer 04 is made of a metal oxide semiconductor material, which has a mobility from 10 cm²/(V·S) to 50 cm²/(V·S). For example, the metal oxide semiconductor material may be any one or more of amorphous indium gallium zinc oxide (a-IGZO), indium gallium zinc tin oxide (IGZTO), indium gallium oxide (IGO) and lanthanide-doped metal oxide Ln-IGZO/IGZTO, so that with the characteristics of relatively great mobility, better uniformity, low process temperature and high light transmittance for visible light of such material, the difficulty of process preparation can be reduced and the process efficiency and the product yield can be improved.

In some implementations, as shown in FIGS. 3u and 3v, the active layer 04 includes at least a source contact region 041, a drain contact region 042, and a channel region 043 sandwiched between the source contact region 041 and the drain contact region 042; the source contact region 041 of the active layer 04 is the source electrode 71, and the drain contact region 042 of the active layer 04 is the drain electrode 72. The display substrate further includes a second insulating structure 08, a third insulating structure, a common electrode 13, a fourth insulating structure 14 and a pixel electrode 15 which are sequentially arranged on a side, away from the substrate 1, of the thin film transistor. The pixel electrode 15 is electrically connected to the drain electrode 72 through a connection via hole sequentially penetrating through the fourth insulating structure 14, the third insulating structure, and the second insulating structure 08. The connection via hole includes a first connection via hole via1 passing through the second insulating structure 08, a second connection via hole passing through the third insulating structure, and a third connection via hole via4 passing through the fourth insulating structure 14; outlines of orthographic projections of the first connection via hole via1, the second connection via hole and the third connection via hole via4 on the base substrate 1 are nested sequentially.

As shown in FIGS. 3q and 3r, the third insulating structure includes a first insulating sub-structure 11 and a second insulating sub-structure 12, and the second connection via hole includes a first sub-via hole via2 penetrating through the first insulating sub-structure 11 and a second sub-via hole via3 penetrating through the second insulating sub-structure 12. Outlines of orthographic projections of the first connection via hole via1, the first sub-via hole via2, the second sub-via hole via3, and the third connection via hole via4 on the base substrate 1 are nested sequentially. With the arrangement of the connection via holes, the phenomenon of disconnection of the pixel electrode 15 caused by the excessively deep connection via hole while forming the pixel electrode 15 can be effectively relieved or avoided.

In some implementations, a ratio of an area of the orthographic projection of the first connection via hole via1 on the active layer 04 to an area of the drain contact region 042 ranges from 1:9 to 1:4, which can ensure that the pixel electrode 15 is stably electrically connected to the drain electrode 72 through the first connection via hole via1, the first sub-via hole via2, the second sub-via hole via3 and the third connection via hole via4. In some implementations, the area of the orthographic projection of the first connection via hole via1 on the drain electrode 72 (i.e., the active layer 04) ranges from 16 μm² to 36 μm².

Alternatively, a size of the orthographic projection of the first connection via hole via1 on the drain electrode 72 may be 4 μm×4 μm, and in a case where the orthographic projection of the first connection via hole via1 on the base substrate 1 does not exceed an orthographic projection of the drain electrode 72 on the base substrate 1, the size of the orthographic projection of the first connection via hole via1 on the drain electrode 72 is set to 4 μm×4 μm, which can ensure that the pixel electrode 15 is electrically connected to the drain electrode 72 stably through the first connection via hole via1.

In some implementations, as shown in FIGS. 3p to 3t, the first connection via hole via1, the first sub-via hole via2, the second sub-via hole via3, or the third connection via hole via4 has a first side edge on a cross section of the base substrate 1 perpendicular to the base substrate 1, and an included angle between a plane passing through the first side edge and perpendicular to the cross section and a plane where the base substrate 1 is located ranges from 110° to 130°. That is, the connection via hole has a slope angle ranging from 50° to 70°. In the present disclosure, with the via holes with the slope angle, the phenomenon of disconnection of the pixel electrode 15 caused by the too deep connection via hole and step difference between the film layers while forming the pixel electrode 15 can be effectively relieved or avoided.

In some implementations, as shown in FIG. 3n, the second insulating structure 08 is provided with first via holes 081, and the bridge structure 9 is electrically connected to the gate electrodes 06 of two adjacent thin film transistors located in the same first pixel group through the two first via holes 081; an orthographic projection of each of the first via holes 081 on the base substrate 1 falls within the orthographic projection of the gate electrode 06 on the base substrate 1, so that the bridge structure 9 can be ensured to be stably electrically connected with the gate electrodes 06 through the first via holes 081.

In some implementations, as shown in FIGS. 30 and 3p, a data line 10 is further disposed on a side of the gate electrode 06 away from the base substrate 1, the data line 10 is configured to provide a data voltage to the thin film transistor, and the bridge structure 9 is disposed in the same layer as the data line 10. It should be understood that the data line 10 may be connected to an external driving circuit through a via hole penetrating through the insulating layer, and other film layer structures other than the second insulating structure 08 through which the data line 10 penetrates are not described in the present disclosure.

In some implementations, the gate electrode 06 is located on a side of the first insulating structure 05 away from the base substrate 1, and the gate electrode 06 includes at least two film layers; the at least two film layers include at least one copper film layer and at least one molybdenum-niobium film layer; alternatively, the at least two film layers include at least one copper film layer and at least one layer of titanium film layer.

The molybdenum-niobium film layer is positioned on a side of the copper film layer close to the base substrate 1; or, the titanium film layer is located on a side of the copper film layer close to the base substrate 1, so that the adhesive force between the gate electrode 06 and the first insulating structure 05 can be improved.

An embodiment of the present disclosure further provides a display device, which includes the display substrate described in any one of the above embodiments. The display device can be any product with a display function, such as a mobile phone, a tablet computer, a television, a display, a notebook computer, a digital photo frame, a vehicle-mounted device and the like. Other essential components of the display device are understood by those skilled in the art, and are not described herein nor should they be construed as limiting the present disclosure.

It will be understood that the above embodiments are merely exemplary embodiments employed to illustrate the principles of the present disclosure, and the present disclosure is not limited thereto. It will be apparent to those skilled in the art that various changes and modifications can be made therein without departing from the spirit and essence of the present disclosure, and these changes and modifications are to be considered within the protective scope of the present disclosure.

1. A display substrate, comprising a base substrate, a buffer layer arranged on the base substrate, and a plurality of pixel units arranged on a side, away from the base substrate, of the buffer layer; wherein the plurality of pixel units constitute a plurality of first pixel unit groups arranged side by side in a second direction, and a plurality of second pixel unit groups arranged side by side in a first direction; each of the first pixel unit groups comprises a plurality of the pixel units arranged side by side in the first direction, and each of the second pixel unit groups comprises a plurality of the pixel units arranged side by side in the second direction; each pixel unit comprises at least one thin film transistor which is correspondingly arranged; wherein
a gate electrode of each thin film transistor is farther away from the base substrate than an active layer of the thin film transistor, and an orthographic projection of the active layer of the thin film transistor on the base substrate covers an orthographic projection of the gate electrode of the thin film transistor on the base substrate; and
the gate electrodes of the thin film transistors of adjacent pixel units in each first pixel unit group are electrically connected through a bridge structure.

2. The display substrate of claim 1, wherein the gate electrode comprises a body structure and a first extension structure and a second extension structure connected to two ends of the body structure, respectively; and an included angle between an extending direction in which the body structure extends and the first direction is a first included angle ranging from 30° to 85°.

3. The display substrate of claim 1, wherein the gate electrode comprises a body structure and a first extension structure and a second extension structure connected to two ends of the body structure, respectively; the first extension structure and the second extension structure are opposite in direction, and an included angle between an extending direction in which each of the first extension structure and the second extension structure extends and the first direction is a second included angle ranging from 0° to 10°.

4. The display substrate of claim 1, wherein an included angle between an extending direction in which the active layer extends and the first direction is a third included angle ranging from 35° to 60°.

5. The display substrate of claim 1, wherein the bridge structure is located between two adjacent pixel units along the second direction.

6. The display substrate of claim 1, further comprising a light shielding layer located on a side of the buffer layer close to the base substrate, wherein an orthographic projection of the light shielding layer on the base substrate at least covers an orthographic projection of a channel region of the active layer on the base substrate.

7. The display substrate of claim 6, wherein a ratio of a first width of the channel region in an extending direction in which the active layer extends to a first width of the light shielding layer in the extending direction in which the active layer extends ranges from 1:7 to 1:4, or
a ratio of a second width of the channel region in a direction perpendicular to an extending direction in which the active layer extends to a second width of the light shielding layer in the direction perpendicular to the extending direction in which the active layer extends ranges from 1:7 to 1:4.

8. (canceled)

9. The display substrate of claim 1, wherein the active layer at least comprises a source contact region, a drain contact region, and a channel region sandwiched between the source contact region and the drain contact region;
the display substrate further comprises a second insulating structure, a third insulating structure, a common electrode, a fourth insulating structure and a pixel electrode which are sequentially arranged on a side of the thin film transistors away from the base substrate, the pixel electrode being electrically connected with the drain contact region through a connection via hole sequentially penetrating through the fourth insulating structure, the third insulating structure and the second insulating structure; and
the connection via hole comprises a first connection via hole penetrating through the second insulating structure, a second connection via hole penetrating through the third insulating structure and a third connection via hole penetrating through the fourth insulating structure, and outlines of orthographic projections of the first connection via hole, the second connection via hole and the third connection via hole on the base substrate are sequentially nested.

10. The display substrate of claim 9, wherein a ratio of an area of an orthographic projection of the first connection via hole on the active layer to an area of the drain contact region ranges from 1:9 and 1:4.

11. The display substrate of claim 9, wherein the second insulating structure is provided with first via holes, and the bridge structure is electrically connected to the gate electrodes of two adjacent thin film transistors in the same first pixel group through two first via holes, respectively; and
an orthographic projection of each of the first via holes on the base substrate falls within the orthographic projection of the gate electrode on the base substrate.

12. The display substrate of claim 1, further comprising a data line located on a side of the gate electrode away from the base substrate, wherein the data line is configured to provide a data voltage to the thin film transistor, and the bridge structure is disposed in a same layer as the data line.

13. A method of manufacturing a display substrate, comprising: providing a base substrate, forming a buffer layer on the base substrate, and forming a plurality of pixel units on a side of the buffer layer away from the base substrate; wherein the plurality of pixel units constitute a plurality of first pixel unit groups arranged side by side in a second direction, and a plurality of second pixel unit groups arranged side by side in a first direction; each of the first pixel unit groups comprises a plurality of the pixel units arranged side by side in the first direction, and each of the second pixel unit groups comprises a plurality of the pixel units arranged side by side in the second direction; the step of forming the pixel units at least comprises: forming thin film transistors on a side of the buffer layer away from the base substrate; wherein
the step of forming the thin film transistors in the pixel units comprises:
sequentially forming a semiconductor layer, a first insulating layer and a first conductive layer on a side of the buffer layer away from the base substrate;
patterning the first conductive layer to form a pattern comprising gate electrodes of the thin film transistors;
patterning, after forming the gate electrodes, the first insulating layer to form a pattern comprising first insulating structures of the thin film transistors;
patterning, after forming the first insulating structures, the semiconductor layer to form a pattern comprising active layers of the thin film transistors; and
forming, after forming the active layers, bridge structures, and each bridge structure electrically connecting the gate electrodes of the thin film transistors in adjacent pixel units in the same first pixel unit group.

14. The method of claim 13, further comprising: forming first gaps between the gate electrodes of the thin film transistors in the pixel units of the same first pixel unit group whiling forming the gate electrodes of the thin film transistors;
forming second gaps between the first insulating structures of the thin film transistors in the pixel units of the same first pixel unit group while forming the first insulating structures; and
forming third gaps between the active layers of the thin film transistors in the pixel units of the same first pixel unit group while forming the active layers; wherein
the first gaps, the second gaps and the third gaps are correspondingly arranged.

15. The method of claim 14, wherein each of the first gaps has a width ranging from 2.5 μm to 4 μm.

16. The method of claim 13, wherein the patterning the first insulating layer to form the pattern comprising the first insulating structures of the thin film transistors comprises:
for each thin film transistor, patterning, by taking the gate electrode of the thin film transistor as a mask plate, the first insulating layer to form a pattern comprising the first insulating structure of the thin film transistor.

17. The method of claim 13, further comprising: after forming the gate electrodes and before forming the bridge structures,
forming a second insulating layer on the base substrate on which the gate electrodes are formed; and
patterning the second insulating layer to form a second insulating structure with first via holes, wherein each bridge structure is electrically connected with the gate electrodes of the thin film transistors in two adjacent pixel units in the same first pixel unit group through two of the first via holes, respectively.

18. The method of claim 17, wherein an area of an orthographic projection of each first via hole on the gate electrode ranges from 16 μm² to 36 μm², or
a minimum boundary of an orthographic projection of each of the first via holes on the gate electrode and boundary of the gate electrode ranges from 6 μm to 12 μm.

19. (canceled)

20. The method of claim 13, wherein the active layer at least comprises a source contact region, a drain contact region, and a channel region sandwiched between the source contact region and the drain contact region, and the method further comprises:
converting, after forming the active layer, the source contact region and the drain contact region into conductors to form a source electrode and a drain electrode;
forming a pattern comprising second insulating structures on the base substrate on which the gate electrodes are formed through a patterning process, the second insulating structure covers the source electrode, the drain electrode and the gate electrode; and
forming a pattern comprising the bridge structures and data lines on a side of the second insulating structure away from the base substrate by a single patterning process, wherein each bridge structure is electrically connected with the gate electrodes of two adjacent thin film transistors in the same first pixel unit group through two first via holes penetrating through the second insulating structures, and each data line is electrically connected with the source electrode through a second via hole penetrating through the second insulating structure.

21. The method of claim 13, further comprising: after forming each thin film transistor,
forming a pattern comprising a third insulating structure on the base substrate on which the gate electrodes are formed by a patterning process;
forming a pattern comprising a common electrode on a side of the third insulating structure away from the base substrate by a patterning process;
forming a pattern comprising a fourth insulating structure on a side of the common electrode away from the base substrate by a patterning process; and
forming a pattern comprising a pixel electrode on a side of the fourth insulating structure away from the base substrate by a patterning process; wherein
the pixel electrode is electrically connected with a drain electrode of the thin film transistor through a connection via hole penetrating through the third insulating structure and the fourth insulating structure.

22. The method of claim 13, further comprising: before forming the buffer layer,
forming a pattern comprising shielding layers corresponding to the thin film transistors one by one on the base substrate by a patterning process, wherein
an orthographic projection of the light shielding layer corresponding to each thin film transistor on the base substrate covers an orthographic projection of a channel region of the active layer of the thin film transistor on the base substrate.
